(19) United States
(12) Patent Application Publication
(10) Pub. No.: US 2026/0276056 A1
(43) Pub. Date: Sep. 17, 2026

(54) DAMPER, METHOD FOR DAMPING, AND APPARATUS INCLUDING A DAMPER

(71) Applicant: ASML Netherlands B.V., Veldhoven (NL)

(72) Inventors: Johannes Hubertus Antonius VAN DE RIJDT, Gemert (NL); Bas Johannes Petrus ROSET, Eindhoven (NL)

(73) Assignee: ASML Netherlands B.V., Veldhoven (NL)

(21) Appl. No.: 19/480,152

(22) PCT Filed: Apr. 26, 2024
(86) PCT No.: PCT/EP2024/061667

§ 371 Date: Oct. 30, 2025

(30) Foreign Application Priority Data
May 26, 2023 (EP) 23175545.5

(51) Int. Cl. F16F 15/08; B33Y 80/00; G03F 7/00

(52) U.S. Cl. CPC F16F 15/08; B33Y 80/00; G03F 7/70716; G03F 7/709; F16F 2224/025; F16F 2226/04

(57) ABSTRACT

The present disclosure provides a damper for an object table, the damper comprising: a pair of plates (22,24) arranged defining a volume (30) between them; a plurality of posts (26) arranged in the volume and extending between the pair of plates; and an elastomeric section (32) enclosing the posts and extending between the plates. The posts may be uniformly distributed over the volume. The damper can be configured to serve as an interface between a magnet assembly and a frame of an actuator.

### CROSS-REFERENCE TO RELATED APPLICATIONS

This application claims priority of EP application 23175545.5 which was filed on 26 May 2023, and which is incorporated herein in its entirety by reference.

### FIELD

The present invention relates to a damper, a method for damping, and an apparatus provided with said damper. The damper may be intended for short range, high acceleration damping. The latter may be applied, for instance, for support of moveable objects, such as a wafer stage in a lithographic apparatus.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

The lithographic apparatus comprises several movable components. For instance the wafer stage, a relatively heavy component for supporting a substrate, is moved over short distances and at a relatively fast rate between respective positions on the substrate. The latter allow irradiation of the same pattern on multiple positions on the substrate, typically arranged in a grid.

To increase throughput of substrates through the lithographic apparatus, the speed and acceleration of the substrate table will have to be increased. However, when exceeding certain speeds and accelerations, the substrate table and components connected thereto start to induce unwanted effects, such as bending, warping, heating, vibrating, etc. To mitigate these effects, dampers can be applied in the actuator design. Furthermore, the servo bandwidth can be increased significantly. The design of these dampers involves a relatively complex balance between, for instance, gain in servo bandwidth, FeedForward model error, internal substrate table deformation error, and reliability.

US20190294057 discloses a stage system for positioning an object, the stage system comprising an object table adapted to support the object to be positioned, and a positioning system adapted to position the object table. The positioning system comprises an actuator adapted to position the object table in a direction of actuation. The actuator comprises a magnet assembly and a coil assembly, and the magnet assembly comprises a first magnetic body and a second magnetic body. The magnet assembly may comprise a damper, which is arranged between and connected to the first magnetic body and the second magnetic body. Optionally, the damper comprises viscoelastic material, for example a natural or synthetic rubber.

US20160238953 discloses a system, wherein the actuator force is applied to the base frame via an interface mass which is mounted to the base frame via a damping member, i.e. a compressible or flexible connection, e.g. a spring or a rubber or rubber-like component. Applying the force via the interface mass provides in a filtering of the applied force.

The disadvantages of the conventional dampers are, for instance, related to the inherent mass of the dampers. The dampers require a frame around the actuator parts, such as the magnets and a shielding iron. The latter may add in the order of 1 kg of mass to the actuator system. Consequently, performance is limited, for instance to acceleration up to a maximum of about 50 m/s2. At such rates of acceleration, induced stresses in the dampers are very high, adding stringent requirements to the manufacturing process of the dampers to meet the specifications.

The present disclosure aims to provide an improved damper system.

### SUMMARY

The present disclosure provides a damper for an object table, the damper comprising:
a pair of plates arranged defining a volume between them;
a plurality of posts arranged in the volume and extending between the pair of plates; and
an elastomeric section enclosing the posts and extending between the plates.

In an embodiment, the posts are uniformly distributed over the volume.

The damper can be configured to serve as an interface between a magnet assembly and a frame of an actuator.

In an embodiment, the posts are comprised of a non-magnetic metal, for instance titanium.

The posts may have a length in the order of 1 to 10 mm and/or a diameter in the order of 0.1 to 0.5 mm.

The elastomeric section may comprise an elastomer. In an embodiment, the elastomeric section comprises a laminated structure.

According to another aspect, the disclosure provides an object table for a lithographic apparatus, the object table comprising, at least:
a base; and
a short stroke module moveable with respect to the base, the short stroke module being provided with one or more magnetic actuators arranged on respective sides of the short stroke module and with at least one damper according to claim 1 arranged between the one or more magnetic actuators and the short stroke module.

According to yet another aspect, the disclosure provides a lithographic apparatus, comprising at least one object table according to claim 8 and/or including at least one damper according to claim 1.

According to an aspect, the disclosure provides a metrology tool for a lithographic process, comprising at least one object table according to claim 8 and/or including at least one damper according to claim 1.

According to yet another aspect, the disclosure provides a method for damping movements of a module, the method comprising the steps of:
providing an apparatus comprising at least one moveable module, the module being provided with at least one actuator;
connecting at least one damper between the at least one actuator and the module, the damper comprising, at least: a pair of plates defining a volume between them; a plurality of posts arranged in the volume and extending between the pair of plates; and an elastomeric section enclosing the posts and extending between the plates; and
moving the module using the at least one actuator.

In an embodiment, the posts are uniformly distributed over the volume.

In an embodiment, the step of connecting at least one damper between the module and the actuator comprises connecting the damper as an interface between a magnet assembly and a frame of the actuator.

In an embodiment, the step of moving the module includes accelerating the module at accelerations exceeding 60 m/s2, for instance exceeding 90 m/s2, for instance exceeding 100 m/s2.

In an embodiment, the method comprises the steps of:
3D printing the posts and the pair of plates, the posts being integral with the plates;
filling the volume between the plates with an elastomer; and
curing the elastomer.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a schematic side view of an object table comprising a long stroke and a short stroke module;

FIG. 3 depicts a perspective view of an object table;

FIG. 4A depicts a perspective view of a magnet assembly including an embodiment of a damper according to the disclosure;

FIG. 4B depicts a perspective view of a magnet assembly including an embodiment of a damper according to the disclosure;

FIG. 4C depicts a cross sectional side view of a magnet assembly;

FIG. 5 depicts a perspective view of an embodiment of an embodiment of a damper according to the disclosure;

FIG. 6 depicts a perspective view of plates provided with a number of posts, suitable for the damper of FIG. 5; and

FIG. 7 depicts a perspective view of an elastomer for the damper of FIG. 5.

FIG. 8 shows results of simulations for behavior of a short stroke module with and without dampers.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

The term “damper” as employed herein refers to a device for reducing mechanical vibration, in particular a shock absorber.

The term “long stroke” as employed herein refers to a section of a device, such as a substrate table, that is able to move over relatively large distances with respect to the lithographic apparatus. Relatively large distances herein may cover a range up to one or several meters.

The term “short stroke” as employed herein refers to a section of the same device, such as the substrate table, that is able to move over relatively short distances with respect to the long stroke section, typically in a range up to one or several millimeters. Although positioning accuracy of the long stroke will typically be optimized, the short stroke section enables significantly higher positioning accuracy. Said higher positioning accuracy may typically be in the nanometer range, i.e. with a precision up to and within 1 nm accuracy with respect to a target position.

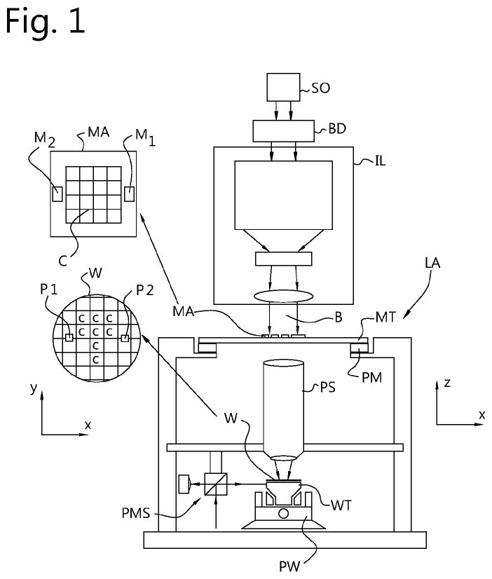

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

As depicted in FIG. 1, the lithographic apparatus is of a transmissive type (e.g. employing a transmissive mask). Alternatively, the apparatus may be of a reflective type (e.g. employing a programmable mirror array of a type as referred to above, or employing a reflective mask).

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axes, i.e., an x-axis, a y-axis and a z-axis. Each of the three axes is orthogonal to the other two axes. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may include an adjuster AD configured to adjust the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may include various other components, such as an integrator IN and a condenser CO. The illuminator may be used to condition the radiation beam, to have a desired uniformity and intensity distribution in its cross section.

The radiation beam B is incident on the patterning device (e.g., mask MA), which is held on the mask support structure (e.g., mask table MT), and is patterned by the patterning device. Having traversed the mask MA, the radiation beam B passes through the projection system PS, which focuses the beam onto a target portion C of the substrate W. With the aid of the second positioning device PW and position sensor IF (e.g. an interferometric device, linear encoder or capacitive sensor), the substrate table WT can be moved accurately, e.g. so as to position different target portions C in the path of the radiation beam B. Similarly, the first positioning device PM and another position sensor (which is not explicitly depicted in FIG. 1) can be used to accurately position the mask MA with respect to the path of the radiation beam B, e.g. after mechanical retrieval from a mask library, or during a scan.

Optionally, the substrate table WT comprises a position measurement system PMS. The position measurement system measures a position of the substrate table with respect to a point of reference. The position measurement system may be encoder based or interferometer based. For details of an interferometer and the use thereof for position measurement, reference is made to, for instance, US2021072088.

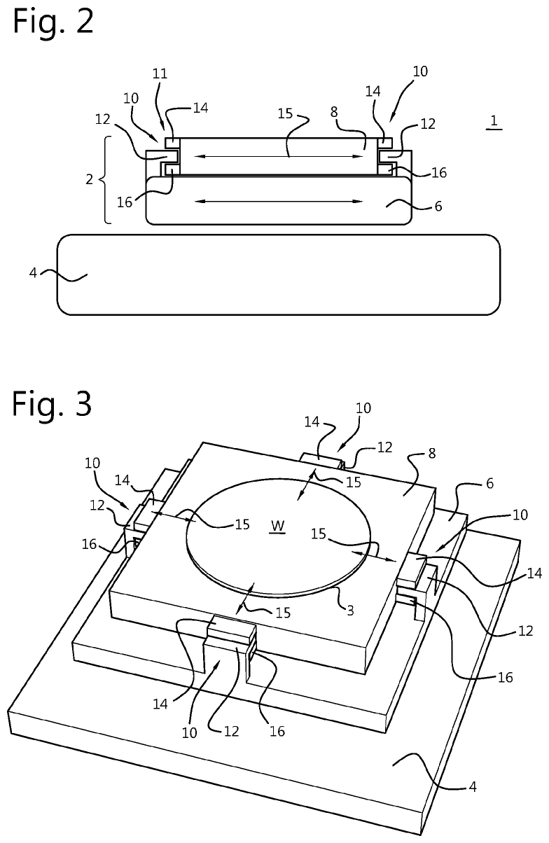

FIG. 2 generally indicates a system 1 comprising an object table 2. The object table may be positioned on a base 4, and typically can move with respect to the base. The object table 2 may include a long stroke section 6 and a short stroke section 8. The object table may be a mask table MT of substrate table WT. Movement of the object table 2 with respect to the base 4 may be realized with the aid of the long-stroke module for relatively coarse positioning and the short-stroke module 8 for fine positioning. Coarse positioning herein may relate to movements over one or more meters distance. A lower limit of positioning accuracy of the long stroke module may typically be limited, for example to an accuracy in the order of μm. Fine positioning relates to the most accurate positioning possible, with an accuracy for instance in the order of nm, for instance in the order of 1 nm.

Referring to FIG. 1, with respect to the mask table MT, the short stoke module 8 and the long stroke module 6 may be part of the first positioning device PM. Movement of the substrate table WT or “substrate support” may be realized using another long-stroke module and a short-stroke module, which may form part of the second positioner PW. In case the lithographic apparatus LA is a stepper (as opposed to a scanner), the mask table MT may be connected to a short-stroke actuator only, or may be fixed.

Mask MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the mask MA, the mask alignment marks may be located between the dies.

The lithographic apparatus could be used in at least one of the following modes:
1. In step mode, the mask table MT or “mask support” and the substrate table WT or “substrate support” are kept essentially stationary, while an entire pattern imparted to the radiation beam is projected onto a target portion C at one time (i.e. a single static exposure). The substrate table WT or “substrate support” is then shifted in the X and/or Y direction so that a different target portion C can be exposed. In step mode, the maximum size of the exposure field limits the size of the target portion C imaged in a single static exposure.
2. In scan mode, the mask table MT or “mask support” and the substrate table WT or “substrate support” are scanned synchronously while a pattern imparted to the radiation beam is projected onto a target portion C (i.e. a single dynamic exposure). The velocity and direction of the substrate table WT or “substrate support” relative to the mask table MT or “mask support” may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.
3. In another mode, the mask table MT or “mask support” is kept essentially stationary holding a programmable patterning device, and the substrate table WT or “substrate support” is moved or scanned while a pattern imparted to the radiation beam is projected onto a target portion C. In this mode, generally a pulsed radiation source is employed and the programmable patterning device is updated as required after each movement of the substrate table WT or “substrate support” or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

FIGS. 2 and 3 show the system 1 comprising the object table 2 and the base 4. An object 3, such as a substrate W, wafer, or mask, may be positioned on the object table 2. Optionally, the object table 2 may comprise an optical element, such as a mirror block.

The system 1 may be adapted to position the object, such as the substrate W, with respect to a reference. The base 4 is optional. The base 4 may be stationary, so that the base 4 can be regarded as a fixed reference. Alternatively, the base 4 may be moveable relative to another fixed reference (for instance, such as a balance mass).

The system 1 may comprise a positioning system adapted to position the object table 2. The positioning system is for example adapted to position the object table 2 in a two dimensional plane, referenced as an x-y plane. The positioning system may be adapted to position the object table 2 in six degrees of freedom. The system 1 may be included in the lithographic apparatus LA.

The base 4 may typically be provided with a long stroke positioner to move the long stroke module 6 of the object table. The positioning system may comprise a short stroke system. The short stroke system of the positioning system may comprise an encoder base, included in the module. The encoder translated positioning instructions. In a practical embodiment, the encoder basically extends over the entire volume of the short stroke module. One or more actuators 10 arranged at respective sides of the short stroke module 8. The short stroke module 8 may for instance comprise at least one actuator 10 on each side of the module. Each actuator 10 may be able to move the module 8 in at least one direction. For instance, each actuator 10 may be able to move the module 8 in one linear direction, indicated by arrows 15. Said linear direction may be perpendicular to the side of the short stroke module, or may be directed along the side of the module.

In the example of FIG. 3, the short stroke module 8 is provide with four actuators 10. Two actuators on opposite sides of the module 8 are adapted to position the module 8 in x-direction with respect to the base 4. Two other actuators 10 on opposite sides of the module 8 are adapted to position the module 8 in the y-direction.

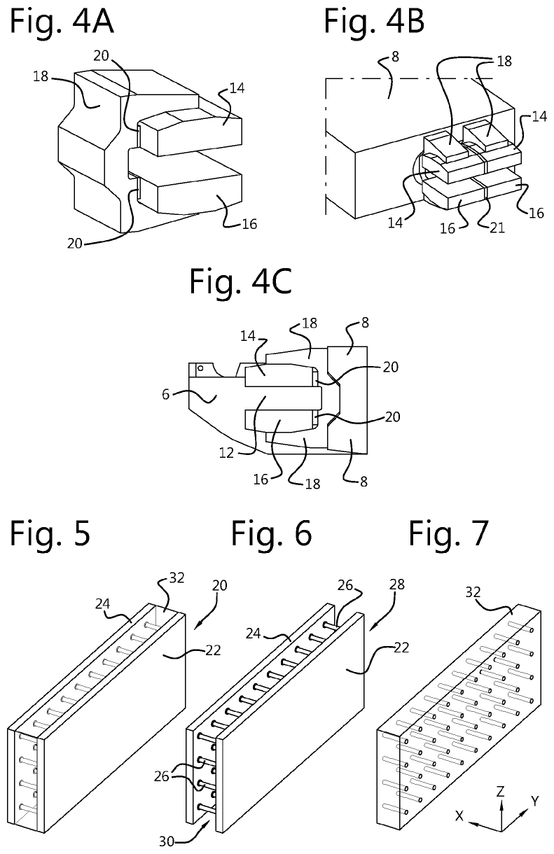

The object table 2 may be provided with any number of actuators 10. For instance referring to FIG. 4B, actuators can also be applied in cooperating pairs, wherein two actuators are arranged side by side.

In addition to the planar movement as exemplified in FIG. 3, the object table 2 may be provided with additional actuators to enable movement in any other degree of freedom. A body has six degrees of freedom to define its position in a space: three translational degrees of freedom and three rotational degrees of freedom. The translational degrees of freedom are generally referred to as the directions x, y and z in a Cartesian coordinate system. The directions x, y and z and mutually perpendicular. The rotational degrees of freedom are generally referred to as the directions rx, ry and rz, wherein rx is a rotation with a rotation axis in the x direction, ry is a rotation with a rotation axis in the y direction and rz is a rotation with a rotation axis in the z direction.

Each actuator 10 may comprise a magnet assembly 11 and a coil 12. The magnet assembly 11 may comprise a first magnetic body 14 and a second magnetic body 16. The magnetic bodies may comprise a magnet. The magnet may be a permanent magnet and/or an electromechanical magnet including an electrical coil and an iron or ferromagnetic core. Preferably, the magnet is a permanent magnet. The magnet assemblies may be enclosed by an enclosure or container, at least partly enclosing the respective magnet while typically having an open side facing the other magnetic body. The container may be referred to as a back-iron. The coil 12 can be activated to act as an electromagnet. Activating the coil 12 will create an electromagnetic force, which moves the magnet assembly 11 with respect to the coil 12. The short stroke module 8 is connected to the magnet assembly and will therefore move as well.

The first magnetic body 14 and the second magnetic body 16 may be attracted to each other due to their respective magnetic forces. Alternatively, the respective force of the first magnetic body 14 and the second magnetic body 16 may repel each other. Either way, the magnetic force is typically directed perpendicular to the direction of actuation 15. In FIGS. 2 and 3, the magnetic force may be directed perpendicular to the x-y plane. The direction of actuation 15 may be in the x-y plane.

The coil assembly 12 extends at least partly between the first magnetic body 14 and the second magnetic body 16. The coil assembly 12 may be connected to the long stroke module 6, or alternatively be fixed to the base 4 (for example if the system lacks a long stroke module and the short stroke module is moveable with respect to the base).

The magnetic bodies 14, 16 may be included in an enclosure 18, which may be referred to as a yoke. The enclosure may be U-shaped. The enclosure may be made of, or comprise, a ceramic and/or a mineral such as Cordierite. The enclosure 18 may be connected to a moveable object, such as the short stroke module 8.

A damper 20 may be provided at the interface between the respective magnetic bodies 14, 16 and the enclosure 18. Another damper 21 may be provided between adjacent magnetic bodies, as exemplified in FIG. 4B.

Generally referring to FIGS. 5, 6 and 7, in an embodiment, the damper 20 comprises two plates, a first plate 22 and a second plate 24. A number of connecting elements such as posts or columns 26 may be provided between the plates 22, 24. The plates 22, 24 may be arranged in parallel to each other. Parallel herein may include plates which are slightly tilted with respect to each other. For instance, the first plate 22 may extend at an angle α with respect to the second plate 24. If the angle a is 0, the two plates are exactly parallel. Said angle α may be in a range up to, for instance, 5 to 20 degrees, for instance about 10 degrees. The plates 22, 24 may be arranged under an angle with respect to each other to, for instance, accommodate for design characteristics and specifications of other equipment. The two plates do not need to be exactly parallel to each other. In a practical embodiment, the two plates 22, 24 realize relatively low shear stiffness with respect to each other, in comparison to the stiffness in the direction perpendicular to the plates. The connecting elements or posts may be connected to the respective plates. Alternatively, the posts may be integral with the respective plates. The assembly 28 of first plate 22, second plate 24, and posts 26 may be made using, for instance, three dimensional (3D) printing techniques.

The pair of parallel plates 22, 24 define a volume 30 between them. The plurality of posts 26 is arranged in the volume 30. An elastomeric section 32 is arranged in the volume 30. The elastomeric section 32 encloses the posts and extends between the plates 22, 24.

In a practical embodiment, the elastomeric section 32 comprises an elastomer. For instance, the elastomeric section may be entirely made of an elastomer. Alternatively, the elastomeric section may comprise a layered or laminated structure of suitable materials, in conjunction providing elasticity or elastomeric behavior. The elastomer may also be referred to as a viscoelastic material. The elastomer may be a rubber or rubber-like material, or a viscoelastic polymer. The material may be EPDM rubber or similar relatively hard rubber. For applications in a lithographic apparatus, which typically operate at modest (for instance 5 kPa) to high vacuum (for instance 5 Pa), an elastomer suitable for use in vacuum is preferred. Examples of the latter include, for instance, elastomer materials as marketed by DuPont™ under trade names such as Hytrel® and Kalrez®.

To fabricate the damper, the assembly 28 of first plate 22, second plate 24, and posts 26 may be made using, for instance, three dimensional (3D) printing techniques. The viscoelastic material may be introduced in the volume between the two plates in uncured form, for instance by pouring or pumping. In a subsequent step, the elastomer material may be cured, for instance using a suitable curing step involving heat and/or a curing agent included in the material.

In a practical embodiment, the posts are substantially uniformly distributed over the volume. In other words, the surfaces of the plates facing the opposite plate are provided with posts. The posts are divided over the surface of the respective plate. In an embodiment, the posts are uniformly divided over the surface. The posts may have any shape and size. In an embodiment, the posts are relatively slim and slender. Thus, the posts allow some bending. For instance, the posts may be substantially round. The surfaces of the respective plates may, for instance, be provided with in the order of 1 to 10 posts per cm². The posts may have a diameter in the order of 0.1 to 0.5 mm, for instance about 0.3 mm. The distance between the plates, and thus the length of the posts, may be in the order of 1 to 50 mm, for instance about 2 to 10 mm, for instance about 5 mm. The posts and the volume may be larger or smaller, depending on the respective application, and the amount of damping and/or stiffness required. In an embodiment the distribution of the connecting elements or posts may be non-uniformly. Such a distribution might be relevant if the force distribution over the plates is for some reason non-uniform due to e.g. a non-uniform stiffness over the counterpart mounting surface to which the plates are mounted, e.g. glued.

For future applications, throughput of substrates per hour may increase, for instance up to 500 substrates per hour. For the short stroke module 8, the acceleration will double compared to present state of the art systems handling 400 substrates per hour (for dry systems). The short stroke acceleration may end up exceeding 100 to 110 m/s². At such accelerations, dampers often lack the overall characteristics to provide sufficient damping over the entire bandwidth.

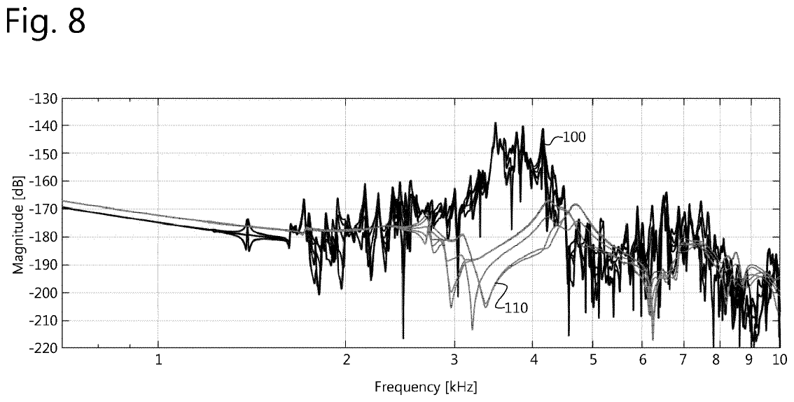

For example, FIG. 8 shows results of simulations for behavior of a short stroke module without dampers, indicated by line 100. Any damping effect originates from the materials included in the short stroke module and the magnet assemblies. At several frequencies, in particular higher order modes, the system shows significant disturbances, hysteresis and vibrations. For a short stroke module, this would require some form of compensation, for instance by allowing the short stroke module time to settle after each move, or by accepting an increased margin of error. Lines 110 indicate modelling results when using a damper according to the present disclosure. The damper of the disclosure provides damping over a large bandwidth. The damper obviates spring like behavior due to the combined characteristics of the elastomer and the posts. The damper dampens main modes of oscillation over a wide frequency range.

The invention enables to obviate a heavy frame enclosing the magnets. Instead, the damper of the disclosure can be connected directly to the magnetic bodies and to the magnet enclosure, for instance by gluing. I.e., the outside surfaces of the plates 22, 24 may be connected to other equipment by gluing. The damper of the disclosure obviates a decoupling leaf spring between the magnets 14, 16 and the back iron, and can be connected directly to the material of the yoke 18.

A suitable adhesive may be, for instance, Scotch-Weld™, marketed by 3M™. Herein, for instance, ScothWeld's Structural Epoxy Adhesive EC-9323-2 B/A or the Scotch-Weld polyurethane adhesive may be suitable.

The material of the plates and the posts may comprise titanium. The titanium may be of grade 1 to grade 23. The posts may comprise a metal composition. The metal composition may be, for instance, Ti6Al4V.

The damper is a combination of elastomeric material (such as rubber) and small solid posts divided over the surface of the volume of the elastomer. The posts are preferably comprised of a metal. The metal may be any metal. In a practical embodiment, the metal is non-magnetic. In an embodiment, the metal is titanium or comprises titanium. Preferably, the metal is non-magnetic for applications near magnets, such as the application for short-stroke module movements, as described above. In an embodiment, the posts are made of titanium or of a titanium composition.

The design of the elastomer and the metal posts is made such that the stiffnesses in the different directions (x, y, z) are such that this gives the optimum result for both a high bandwidth and low internal chuck deformation error (expressed as an Interest to Control Error, or ICE). Internal chuck deformation error herein refers to mechanical deformations of the short stroke module 8 at the relatively fast rates of acceleration as described above.

Simulations using accelerations of 110 m/s2 and speeds up to 1.6 m/s (corresponding to throughput up to 500 substrates per hour) have provided results indicated in the table below. Herein, sizes and controller settings were similar for both options, using the same ratios for Jerk-to-Acceleration and Snap-to-Jerk. The dampers using elastomer only well exceeded the limits for chuck deformation error ICE and are therefore unfeasible to achieve the higher throughput aimed for. In other words, dampers with rubber only result, when exceeding a certain level of acceleration, in deformations in the connected substrate stage beyond acceptable limits. Simulations are for posts having a diameter in the order of 0.3 mm and a length of about 5 mm. Said length, corresponding to a thickness of the elastomer, provides optimal values for low ICE. When using the damper of the present disclosure, the chuck deformation error is very low, and remains well within the acceptable limits or specification threshold:

| | MA-x [nm] | MA-y [nm] |
|---|---|---|
| ICE | max | max |
| Specification (threshold) | 0.45 | 0.45 |
| Elastomer (FIG. 7) | 3.50 | 5.46 |
| Elastomer and posts (FIG. 5) | 0.06 | 0.07 |

Simulations have provided the following exemplary values for stiffness of respective parts of the damper:

| | Metal posts | Elastomer @1 | Assembly of posts and |
|---|---|---|---|
| Stiffness | (FIG. 6) | kHz (FIG. 7) | elastomer (FIG. 5) |
| x [N/m] | 1E+08 | 4E+07 | 1.4E+08 |
| y [N/m] | 2E+06 | 2E+06 | 4.0E+06 |
| z [N/m] | 2E+06 | 2E+06 | 4.0E+06 |
| Rₓ [Nm / rad] | 8E+01 | 8E+01 | 1.6E+02 |
| R_{y} [Nm / rad] | 6E+02 | 8E+01 | 6.8E+02 |
| R_{z} [Nm / rad] | 4E+03 | 8E+02 | 4.8E+03 |

The exemplary values in the table above indicate that a balance between stiffness of the elastomer and stiffness of the metal posts can provide an optimal performance when combined in an assembly. Moreover, compared to the damper with elastomer only, the damper of the present disclosure enables to increase the controller bandwidth, for instance from about 350 Hz (elastomer damper only), to about 500 Hz (when using dampers according to the disclosure). Also, the weight of the short stroke module can be reduced, for instance from about 17 kg (conventional system), to about 13 to 14 kg (when using the dampers according to the present disclosure).

With the damper of the disclosure, the following can be achieved:
Mass reduction of about 3 kg of the short stroke module 8 for enabling accelerations up to about 110 m/s² with the same actuator magnets and back irons.
Bandwidth of about 500 Hz for the critical horizontal directions.
ICE error<0.1 nm at virtually no (“0” ins) settling time. As settling time can be obviated, exposure can follow immediately after movement of, for instance, the substrate table. This typically saves in the order of milliseconds per exposure. As the lithographic apparatus referenced above typically operates virtually non-stop, these saved milliseconds add to improved overall throughput and performance.
Stress in the damper at high acceleration forces is well within mechanical constraints of respective materials involved, for instance: <2 N/mm² for the adhesive; <50 N/mm² for the Titanium posts; and <0.5 N/mm² for the elastomer. Please note that in particular the stress limit of the adhesive is a limiting factor, and typically cannot be met when using conventional dampers.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Embodiments include the following numbered clauses:
1. A damper for an object table, the damper comprising:
   a pair of plates arranged defining a volume between them;
   a plurality of posts arranged in the volume and extending between the pair of plates; and
   an elastomeric section enclosing the posts and extending between the plates.
2. The damper of clause 1, wherein the posts are uniformly distributed over the volume.
3. The damper of clause 1 or 2, being configured to serve as an interface between a magnet assembly and a frame of an actuator.
4. The damper of one of the previous clauses, wherein the posts are comprised of a non-magnetic metal, for instance titanium.
5. The damper of one of the previous clauses, wherein the posts have a length in the order of 1 to 10 mm and/or a diameter in the order of 0.1 to 0.5 mm.
6. The damper of one of the previous clauses, wherein the elastomeric section comprises an elastomer.
7. The damper of one of the previous clauses, wherein the elastomeric section comprises a laminated structure.
8. An object table for a lithographic apparatus, the object table comprising, at least:
   a base; and
   a short stroke module moveable with respect to the base, the short stroke module being provided with one or more magnetic actuators arranged on respective sides of the short stroke module and with at least one damper according to clause 1 arranged between the one or more magnetic actuators and the short stroke module.
9. Lithographic apparatus, comprising at least one object table according to clause 8 and/or including at least one damper according to clause 1.
10. Metrology tool for a lithographic process, comprising at least one object table according to clause 8 and/or including at least one damper according to clause 1.
11. Method for damping movements of a module, the method comprising the steps of:
   providing an apparatus comprising at least one moveable module, the module being provided with at least one actuator;
   connecting at least one damper between the at least one actuator and the module, the damper comprising, at least: a pair of plates defining a volume between them; a plurality of posts arranged in the volume and extending between the pair of plates; and an elastomeric section enclosing the posts and extending between the plates; and
   moving the module using the at least one actuator.
12. The method of clause 11, wherein the posts are uniformly distributed over the volume.
13. The method of clauses 11 or 12, the step of connecting at least one damper between the module and the actuator comprising connecting the damper as an interface between a magnet assembly and a frame of the actuator.
14. The method of one of clauses 11 to 13, the step of moving the module including accelerating the module at accelerations exceeding 60 m/s2, for instance exceeding 90 m/s2, for instance exceeding 100 m/s2.
15. The method of one of clauses 11 to 14, comprising the steps of:
   3D printing the posts and the pair of plates, the posts being integral with the plates;
   filling the volume between the plates with an elastomer; and
   curing the elastomer.
16. A damper for an object table, the damper comprising:
   a pair of opposing plates arranged to define a volume in between them;
   a plurality of connecting elements arranged in the volume and extending between the pair of plates; and
   an elastomeric section enclosing the connecting elements and extending between the pair of plates.
17. The damper of clauses 16, wherein the connecting elements are uniformly distributed over the volume.
18. The damper of clauses 16 or 17, being configured to serve as an interface between a magnet assembly and a frame of an actuator.
19. The damper of any one of clauses 16-18, wherein the connecting elements are comprised of a non-magnetic metal, for instance titanium.
20. The damper of any one of clauses 16-19, wherein the connecting elements have a length in the order of 1 to 10 mm and/or a diameter in the order of 0.1 to 0.5 mm.
21. The damper of any one of clauses 16-20, wherein the elastomeric section comprises an elastomer.
22. The damper of any one of clauses 16-21, wherein the elastomeric section comprises a laminated structure.
23. An apparatus including at least one damper according to clause 16.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1.-23. (canceled)

24. A damper for an object table, the damper comprising:
a pair of plates arranged defining a volume between them;
a plurality of posts arranged in the volume and extending between the pair of plates; and
an elastomeric section enclosing the posts and extending between the plates.

25. The damper of claim 24, wherein the posts are uniformly distributed over the volume.

26. The damper of claim 24, wherein the damper is further configured to be disposed as an interface between a magnet assembly and a frame of an actuator.

27. The damper of claim 24, wherein the posts are comprised of a non-magnetic metal or titanium.

28. The damper of claim 24, wherein the posts have a length on the order of 1 to 10 mm and/or a diameter on the order of 0.1 to 0.5 mm.

29. The damper of claim 24, wherein the elastomeric section comprises an elastomer.

30. The damper of claim 24, wherein the elastomeric section comprises a laminated structure.

31. A lithographic apparatus, comprising at least one damper of claim 24.

32. A method for damping movements of a module, the method comprising:
providing an apparatus comprising at least one moveable module, the module being provided with at least one actuator;
connecting at least one damper between the at least one actuator and the module, the damper comprising, at least
a pair of plates defining a volume between them;
a plurality of posts arranged in the volume and extending between the pair of plates; and
an elastomeric section enclosing the posts and extending between the plates; and
moving the module using the at least one actuator.

33. The method of claim 32, further comprising uniformly distributing the posts over the volume.

34. The method of claim 32, the connecting at least one damper between the module and the actuator comprising connecting the damper as an interface between a magnet assembly and a frame of the actuator.

35. The method of claim 32, the moving the module comprises accelerating the module at accelerations exceeding 60 m/s2, exceeding 90 m/s2, or exceeding 100 m/s2.

36. The method of claim 32, comprising:
3D printing the posts and the pair of plates, the posts being integral with the plates;
filling the volume between the plates with an elastomer; and
curing the elastomer.

37. A damper for an object table, the damper comprising:
a pair of opposing plates arranged to define a volume in between them;
a plurality of connecting elements arranged in the volume and extending between the pair of plates; and
an elastomeric section enclosing the connecting elements and extending between the pair of plates.

38. The damper of claim 37, wherein the connecting elements are uniformly distributed over the volume.

39. The damper of claim 37, wherein the damper is configured to be disposed as an interface between a magnet assembly and a frame of an actuator.

40. The damper of claim 37, wherein the connecting elements comprise of a non-magnetic metal or titanium.

41. The damper of claim 37, wherein the connecting elements have a length on the order of 1 to 10 mm and/or a diameter on the order of 0.1 to 0.5 mm.

42. The damper of claim 37, wherein the elastomeric section comprises an elastomer.

43. The damper of claim 37, wherein the elastomeric section comprises a laminated structure.
